(19) United States
(12) Patent Application Publication
(10) Pub. No.: US 2025/0140520 A1
(43) Pub. Date: May 1, 2025

(54) APPARATUS AND METHOD FOR TWO-DIMENSIONAL ION BEAM PROFILING

(71) Applicant: Axcelis Technologies, Inc., Beverly, MA (US)

(72) Inventors: Michael Cristoforo, Beverly, MA (US); Bo Vanderberg, Gloucester, MA (US)

(21) Appl. No.: 18/919,483

(22) Filed: Oct. 18, 2024

Related U.S. Application Data
(60) Provisional application No. 63/594,963, filed on Nov. 1, 2023.

(51) Int. Cl. H01J 37/304; H01J 37/317

(52) U.S. Cl. CPC H01J 37/304; H01J 37/3171; H01J 2237/30483

(57) ABSTRACT

A profiling apparatus has a hollow cylinder having a circumferential slit having a circumferential slit width disposed about cylinder axis. Two or more beam current detectors are disposed within the cylinder to determine a respective beam current of an ion beam received at respective detector surfaces. An aperture plate is upstream of the cylinder and has an aperture slit running parallel to the cylinder having a slit width. A rotary input apparatus controls a rotational position of the cylinder. A linear translation apparatus controls a linear position of the cylinder and aperture plate. A controller determines a uniformity and angular profile of the ion beam in a plurality of dimensions based, at least in part, on the rotational position of the cylinder, the linear position of the cylinder and aperture plate, and the respective beam current of the ion beam received.

### REFERENCE TO RELATED APPLICATIONS

This application claims the benefit of U.S. Provisional Application No. 63/594,963 filed Nov. 1, 2023, entitled “APPARATUS AND METHOD FOR TWO-DIMENSIONAL ION BEAM PROFILING”, the contents of which are herein incorporated by reference in their entirety.

### FIELD OF THE INVENTION

The present invention relates generally to ion implantation systems, and more specifically to systems and methods for obtaining a desired two-dimensional current density profile of an ion beam as well as a desired angular distribution in ion implantation systems.

### BACKGROUND OF THE INVENTION

Ion implantation is the precise placement of atoms into solid matter with controlled location and concentration within the solid. It is used in many applications in the manufacture of semiconductor devices, to dope semiconductors with impurities or dopants, to modify the physical properties of the solid such as surface roughness, to alter the work function of the solid, or to form passivation layers, to name a few. The equipment used to implant ions is called an ion implanter, and the most common use of ion implanters is to treat semiconducting wafers with an ion beam in order to produce n- or p-type extrinsic material doping. As an example, when used for doping silicon, the ion implanter injects a selected extrinsic species to produce the desired semiconducting material. Implanting ions such as antimony, arsenic or phosphorus results in “n type” extrinsic material wafers, whereas if “p type” extrinsic material wafers are desired, boron or indium may be implanted.

Typical ion implanters include an ion source for generating positively charged ions from ionizable source materials. The generated ions are energized, formed into a beam and directed along a predetermined beam path to an implantation station. The ion implanter may include beam forming and shaping structures extending between the ion source and the implantation station. The beam forming and shaping structures maintain the ion beam and bound an elongated interior cavity or passageway through which the beam passes en route to the implantation station. When operating an implanter, this passageway can be evacuated to reduce the probability of ions being deflected from the predetermined beam path as a result of collisions with gas molecules.

Trajectories of charged particles of given kinetic energy in a magnetic field will differ for different masses (or charge-to-mass ratios) of these particles. Therefore, the part of an extracted ion beam which reaches a desired area of a semiconductor wafer or other target after passing through a constant magnetic field can be made pure since ions of undesirable molecular weight will be deflected to positions away from the beam and implantation of other than desired materials can be avoided. The process of selectively separating ions of desired and undesired charge-to-mass ratios is known as mass analysis. Mass analyzers typically employ a mass analysis magnet creating a dipole magnetic field to deflect various ions in an ion beam via magnetic deflection in an arcuate passageway which will effectively separate ions of different charge-to-mass ratios.

### SUMMARY

The present disclosure thus provides a system and method for controlling an ion implantation system and providing a desired current density profile and angle distribution of an ion beam. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one exemplary aspect of the present disclosure, a profiler apparatus is provided for determining a profile of an ion beam along a beam path. The profiler apparatus, for example, comprises a hollow cylinder comprising a circumferential slit defined therethrough. A rotation apparatus is operably coupled to the hollow cylinder, for example, wherein the rotation apparatus is configured to selectively rotate the hollow cylinder about a first axis, thereby defining a rotational position of the circumferential slit.

An aperture plate is further provided for the profiler apparatus, wherein the aperture plate has a defining aperture slit defined therethrough. The aperture plate, for example, is fixed relative to the pair of current detection apparatus, wherein the defining aperture slit is positioned a predetermined distance upstream of the hollow cylinder along the beam path. A translation apparatus, in one example, is operably coupled to the hollow cylinder and the aperture plate, wherein the translation apparatus is configured to translate the hollow cylinder and the aperture plate along the second axis, thereby defining a linear position of the aperture slit.

In another example, the profiler apparatus further comprises a current detection apparatus comprising a first current detector and a second current detector. The first current detector and the second current detector, for example, are positioned within the hollow cylinder and configured to detect a respective first current and second current of ions of the ion beam passing through the aperture slit and circumferential slit and impacting thereon concurrent with the rotation of the hollow cylinder.

Further, the profiler apparatus comprises a controller configured to determine a first uniformity of current density of the ion beam defined along the first axis, a second uniformity of current density of the ion beam defined along the second axis, and an angle of incidence of the ion beam with respect to the first axis based, at least in part, on the first current, the second current, the rotational position of the circumferential slit, and a linear position of the aperture slit.

One or more feedback apparatuses can be further provided, wherein the one or more feedback apparatuses are configured to provide one or more of the rotational positions of the circumferential slit and the linear position of the aperture slit to the controller. In one example, the second uniformity of current density of the ion beam is based on a sum of the first current and the second current at the rotational position of the circumferential slit and the linear position of the aperture slit.

In accordance with one example, the circumferential slit extends from a first radial position to a second radial position with respect to the first axis, thereby defining an angular span of the circumferential slit. The angular span, for example, is less than 360 degrees. In a particular example, the angular span is between 90 degrees and 360 degrees.

The profiler apparatus of the present disclosure is particularly advantageous when the ion beam comprises a ribbon ion beam, which can either be static or comprised of a scanned pencil or spot beam, where the spot beam is scanned along the second axis. The circumferential slit and the defining aperture slit, for example, have respective widths that are smaller than a width of the ribbon ion beam.

In accordance with another aspect of the disclosure, a profiler apparatus for profiling an ion beam is provided, wherein the profiler apparatus comprises an aperture plate having an aperture slit defined therein, wherein the aperture slit extends parallel to a first axis. A hollow cylinder extends parallel to the first axis, wherein the hollow cylinder comprises a cylinder wall having a circumferential slit defined therein, and wherein the hollow cylinder is rotatable about the first axis. A pair of detectors are positioned along or parallel to the first axis within the hollow cylinder, wherein the pair of detectors are fixed with respect to the aperture plate and configured to respectively detect a current of at least a portion of the ion beam as the at least a portion of the ion beam passes through the aperture slit and the circumferential slit. Further, a translation apparatus is configured to translate the aperture plate, hollow cylinder, and pair of detectors along, or with respect to, a second axis, wherein the second axis is approximately perpendicular to the first axis.

In one example, the profiler apparatus further comprises a controller configured to determine a first uniformity of the ion beam defined along the first axis, a second uniformity of the ion beam defined along the second axis, and an angle of incidence of the ion beam with respect to the first axis based, at least in part, on a rotational position of the circumferential slit, and a linear position of the aperture slit, and the respective current of the at least a portion of the ion beam.

In another example, a rotation apparatus is further operably coupled to the hollow cylinder and configured to selectively rotate the hollow cylinder about the first axis. In a further example, the aperture slit is positioned a predetermined distance upstream of the hollow cylinder with respect to a path of the ion beam.

In accordance with yet another example aspect of the disclosure, a profiler apparatus for determining a profile of a scanned ion beam along a beam path is provided, wherein the profiler apparatus comprises a cylinder apparatus, and wherein the cylinder apparatus comprises a first detector positioned along the beam path and extending parallel to a first axis. The first detector, for example, is configured to detect a first current of at least a portion of the scanned ion beam upon exposure thereto. A second detector of the cylinder apparatus, for example, is positioned along the beam path and extending parallel to a first axis, wherein the second detector is configured to detect a second current of the portion of the scanned ion beam upon exposure thereto. The cylinder apparatus, for example, further comprises a rotary input apparatus and a hollow cylinder operably coupled to the motor. The rotary input apparatus, for example, is configured to selectively rotate the hollow cylinder about the first axis, wherein the hollow cylinder comprises a cylinder wall encircling the first detector and the second detector, and wherein the cylinder wall comprises a circumferential slit defined therethrough.

An aperture plate, for example, is further provided, wherein the aperture plate has an aperture slit defined therethrough. The aperture slit extends parallel to the first axis and is defined by an aperture slit width extending along a second axis that is approximately perpendicular to the first axis. The aperture slit, for example, is positioned a predetermined distance upstream of the hollow cylinder along the beam path.

A translation apparatus, for example, is operably coupled to the cylinder apparatus and the aperture plate, wherein the translation apparatus is configured to translate the cylinder apparatus and the aperture plate along, or with respect to, the second axis. Further, a controller is configured to determine a first uniformity of the scanned ion beam along the first axis, a second uniformity of the scanned ion beam along the second axis, and an angle of incidence of the scanned ion beam with respect to the first axis based, at least in part, on the first current, the second current, a rotational position of the circumferential slit, and a linear position of the aperture slit. The second uniformity of current density of the ion beam, for example, is based on a sum of the first current and the second current at the rotational position of the circumferential slit and the linear position of the aperture slit.

One or more feedback apparatuses, for example, are further provided, wherein the one or more feedback apparatuses are configured to provide one or more of the rotational positions of the circumferential slit and the linear position of the aperture slit to the controller. The one or more feedback apparatuses, for example, comprise a linear encoder operably coupled to the translation apparatus and a rotational encoder operably coupled to the cylinder apparatus.

Further, each of the first detector and the second detector can comprise a respective detector surface facing the scanned ion beam, wherein the first detector and the second detector are stationary with respect to the aperture plate.

To the accomplishment of the foregoing and related ends, the disclosure comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 illustrates an ion implantation system in accordance with an example aspect of the present disclosure.

FIG. 2 is a perspective representation of portions of a beam profiling apparatus in accordance with various examples of the present disclosure.

FIG. 3 is a perspective representation of a cylinder of a beam profiling apparatus in accordance with various examples of the present disclosure.

FIG. 4 is a perspective representation of portions of a beam profiling apparatus in accordance with various examples of the present disclosure.

FIG. 5 is a schematic representation of a beam profiling apparatus for a scanned ion beam in accordance with various examples of the present disclosure.

FIG. 6 is a schematic cross-sectional representation of a scanned ion beam illustrating angle of implantation in accordance with still further various examples of the present disclosure.

FIG. 7 illustrates an example methodology for determining a profile of an ion beam in accordance with another aspect of the present disclosure.

### DETAILED DESCRIPTION OF THE INVENTION

The present disclosure provides an ion implantation system and method for determining and controlling angles and uniformity of an ion beam, such as when controlling ion implantation in a semiconductor workpiece. Further, a system and method for accurately and expeditiously tuning the ion beam are provided by measuring beam current through a rotating circumferential slit positioned behind an aperture that translates through the ion beam.

Accordingly, the present invention will now be described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment and may also or alternatively be fully or partially implemented in a common feature or circuit in another embodiment. For example, several functional blocks may be implemented as software running on a common processor, such as a signal processor. It is further to be understood that any connection which is described as being wire-based in the following specification may also be implemented as a wireless communication, unless noted to the contrary.

In so-called hybrid scan ion implantation, implanting ions into a workpiece can include producing and measuring a scanned ion beam along a beam path. A scanned ion beam is produced by extracting ions from an ion source to form a spot ion beam or so-called “pencil” beam. The pencil beam, for example, can be scanned along an axis (e.g., an x-axis) via a scanner magnet in order to produce a scanned ion beam (e.g., a ribbon beam) of sufficient width and uniformity to provide adequate coverage across the workpiece along the x-axis. The scanned ion beam subsequently enters a collimator (e.g., a collimating magnet) to correct angular errors associated with the scanning, whereby the scanned and corrected ion beam then enters a process chamber for implanting of the ions into the workpiece. The workpiece, for example, can be translated along a y-axis by a mechanical scanning system (e.g., a robot) in order to attain a uniform dose distribution of implanted ions across the workpiece.

In such a hybrid scan ion implanter, the combination of providing the scanned and corrected ion beam in the x-axis and the mechanical translation of the workpiece along the y-axis can produce a uniform concentration of ions throughout the surface of the workpiece. However, due to various issues associated with generating, scanning, and transporting the ion beam along the beam path, all ions within the ion beam may not have an identical direction across the entire width of ion beam. The resulting misdirection can be a cause of current density non-uniformity as well as angle uniformity and average angle errors when implanted into the workpiece.

In an attempt to correct dose uniformity, a profiler can be translated along the x-axis of the scanned ion beam to collect beam current data, whereby the beam current data is analyzed to make adjustments to the scanning speed of the scanner magnet. This method of measuring and adjusting is iterated several times in order to produce an ion beam having characteristics falling within a desired dose uniformity specification.

Angle effects caused by channeling or other implant damage effects can prescribe some control of average angle and divergence. As modern semiconductor devices become more complex, for example, the microrelief of the implanted workpiece can be non-planar, and issues relating to the measurement of the angle distribution of the ion beam can arise, as well as issues relating to tuning of the implantation system in order to achieve an ion beam with the desired angle distribution.

Tuning an implantation system for an ion beam having a desired angle distribution can be dependent on the measurement of that very angle distribution, and how such a measurement is performed. An implant process can require that the desired dose uniformity is achieved with simultaneous compliance to the angle requirements, and angle errors are conventionally measured and corrected. In order to correct angle errors, a method similar to the aforementioned uniformity correction can be performed. However, in order to detect angles and correct angle errors, a mask is placed in front of the profiler during data collection. The resulting data is then analyzed and fed back to the collimator and other angle correcting optics. Again, this method of measuring and adjusting angles can take several iterations to produce an ion beam within a desired angle specification. It should be noted that, during x-axis angle correction, no y-axis angle information has been previously obtained. As such, no information has been fed back to the y-axis mechanical scanning system for correction of y-axis angle.

One of the difficulties in tuning the ion implanter for an ion beam to have the greatest uniformity and smallest angle distribution is that the tuning is often a serial process with multiple iterations, as there has been no real-time feedback mechanism for measuring the uniformity and angle distribution while adjusting or otherwise tuning each of these various parameters of the ion implanter. Tuning the ion implanter in such a serial manner of tuning, measuring, tuning, measuring, etc. can be time-consuming, thus decreasing the productivity of the ion implanter.

The present disclosure advantageously increases the productivity of an ion implanter to provide efficient measuring and tuning of the implanter for maximum uniformity with an optimal angle distribution. The present disclosure thus provides various systems, apparatuses, and methods for controlling uniformity and angular content of a scanned ion beam at a workpiece plane, whereby a device is provided to measure the scanned ion beam to provide feedback to correct both uniformity errors and angle errors along a width of an ion beam that is scanned along an x-axis, whereby a workpiece is mechanically translated along a y-axis.

The present disclosure provides a beam profiler apparatus that is configured to measure current density distribution, from which x-axis beam uniformity, x-axis beam angles, and y-axis beam uniformity can be calculated, as well as a y-axis position of the ion beam within the beam path and an overall height in the y-direction of the ion beam. The position within the beam path, for example, can be controlled with beam steering devices such as an angular energy filter (AEF). Similarly, the overall height of the beam can be controlled with imaging and focusing optics, such as ion source extraction optics. An understanding of the overall height of the beam, for example, can provide for productivity enhancement by optimizing a length of a mechanical scan of the workpiece through the ion beam.

The beam profiler apparatus of the present disclosure, for example, is configured to concurrently measure uniformity of the ion beam in both the x-axis and the y-axis. Furthermore, in accordance with the present disclosure, an angle of incidence of individual ion beamlets of the scanned ion beam to the workpiece plane can be advantageously determined utilizing the information already obtained through the uniformity measurements from the beam profiler apparatus.

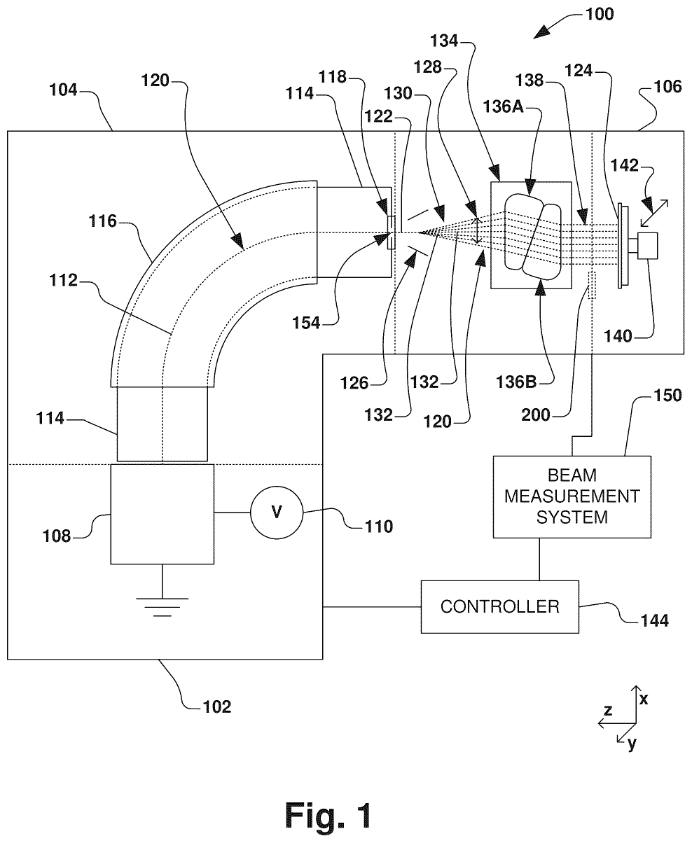

In order to gain a better understanding of the present disclosure, an example ion implantation system 100 is illustrated in FIG. 1 in accordance with various aspects of the present disclosure. The ion implantation system 100 is presented for illustrative purposes and it is appreciated that aspects of the invention are not limited to the described ion implantation system and that other suitable ion implantation systems of varied configurations can also be employed.

The ion implantation system 100 is illustrated having a terminal 102, a beamline assembly 104, and an end station 106. In some examples, the terminal 102 can be considered as comprising the beamline assembly 104. The terminal 102, for example, comprises an ion source 108 powered by a high voltage power supply 110, wherein the ion source produces and directs an ion beam 112 through the beamline assembly 104, and ultimately, to the end station 106. While referred to generally as the ion beam 112 as it travels throughout the ion implantation system 100, for example, it shall be appreciated that the ion beam can take the form of a spot beam or pencil beam, ribbon beam, or any other shaped beam. The beamline assembly 104 further has a beamguide 114 and a mass analyzer 116, wherein a dipole magnetic field is established to pass only ions of appropriate charge-to-mass ratio through an aperture 118 at an exit end of the beamguide 114 to define a mass analyzed ion beam 122 directed along a beam path 120 toward a workpiece 124 (e.g., a semiconductor wafer, display panel, etc.) positioned in the end station 106.

In accordance with one example, an ion beam scanning apparatus 126, such as an electric or magnetic scanner (referred to generically as a “scanner”), is configured to scan the mass analyzed ion beam 122 in at least a first direction 128 (e.g., the +/−x-direction, also called a first scan path or “fast scan” axis, path, or direction) with respect to the workpiece 124, therein defining a ribbon-shaped ion beam or scanned ion beam 130 comprised of a plurality of beamlets 132.

The scanned ion beam 130 is then passed through a collimator 134 (e.g., a parallelizer/corrector component, also called a “corrector magnet”), which comprises two dipole magnets 136A, 136B in the illustrated example. The dipole magnets 136A, 136B, for example, are substantially trapezoidal and oriented to mirror one another to cause the plurality of beamlets 132 of the scanned ion beam 130 to bend into a substantially S-shape. Stated another way, the dipole magnets 136A, 136B of the present example have equal angles and radii and opposite directions of curvature.

The collimator 134, for example, causes the scanned ion beam 130 to alter its beam path such that the plurality of beamlets 132 of the scanned beam travel parallel to a beam axis (e.g., the z-axis) regardless of the scan angle initially imparted by the ion beam scanning apparatus 126. It will be appreciated that the collimator 134 may comprise any suitable number of electrodes or magnets arranged and biased to focus, bend, deflect, converge, diverge, scan, parallelize and/or decontaminate the scanned ion beam 130 to define a parallelized ion beam 138. As a result, the implantation angle is relatively uniform across the workpiece 124. In one example, the collimator 134 can also act as a deflecting component, such that neutrals generated upstream of the collimators will not follow the nominal path defined by the collimator, and thus have a lower probability of reaching the workpiece 124 in the end station 106.

Furthermore, in the present example, a workpiece scanning apparatus 140 is provided, wherein the workpiece scanning apparatus is configured to selectively scan the workpiece 124 through the ion beam 112 (e.g., the parallelized ion beam 138) in at least a second direction 142 (e.g., the +/−y-direction, also called a second scan path or “slow scan” axis, path, or direction). The ion beam scanning apparatus 126 (also called a scanner or scanning element) and the workpiece scanning apparatus 140, for example, may be instituted separately, or in conjunction with one another, in order to provide the desired scanning of the workpiece 124 relative to the parallelized ion beam 138. In another example, the mass analyzed ion beam 122 is electrically scanned in the first direction 128, therein producing the scanned ion beam 130, and the workpiece 124 is mechanically scanned in the second direction 142 through the plurality of beamlets 132 of the parallelized ion beam 138. Such a combination of electric and mechanical scanning of the ion beam 112 and workpiece 124 produces what is called a “hybrid scan”. The present invention is applicable to all combinations of scanning of the workpiece 124 relative to the ion beam 112, or vice versa.

It is appreciated that different types of end stations 106 may be employed in the ion implantation system 100. For example, a “batch” type end station can simultaneously support multiple workpieces 124 on a rotating support structure (not shown), wherein the workpieces are rotated through the ion beam 112 until all the workpieces are completely implanted. A “serial” type end station, as shown in FIG. 1, on the other hand, supports a single workpiece 124 along the beam path for implantation, wherein multiple workpieces are implanted one at a time in a serial manner, whereby each workpiece is individually implanted before another workpiece is positioned for implantation.

A controller 144, for example, is further provided, wherein the controller is configured for individual or overall control of the various components of the ion implantation system 100 discussed above. For example, the controller 144 is configured to selectively control one or more of the ion source 108, mass analyzer 116, ion beam scanning apparatus 126, collimator 134, and workpiece scanning apparatus 140 based on various inputs, such as operator input or various feedback mechanisms.

According to another exemplary aspect of present disclosure, a beam measurement system 150 is further provided, whereby the beam measurement system can provide feedback related to parallelized ion beam 138. The beam measurement system 150, for example, is configured to determine one or more properties associated with the ion beam 112 and to provide such information to the controller 144. A system and method for measuring the angle of the ions incident to the workpiece 124, as well as a calibration of said measurement to the crystal planes of the workpiece has been provided in a so-called “Optima XE” ion implantation system and commonly-owned U.S. Pat. No. 7,361,914 to Robert D. Rathmell et al., the contents of which are hereby incorporated by reference in its entirety. In accordance with the present disclosure, the beam measurement system 150 is configured to not only measure the angle of incidence of the ion beam 112 with respect to the workpiece 124, but is further configured to determine a vertical size of the ion beam 112 that has not been previously achieved.

In accordance with one example, the beam measurement system 150 can be provided within, or proximate to, the end station 106 near the location of the workpiece 124, whereby various calibration measurements can be attained prior to implantation operations. During calibration, the ion beam 112 passes through the beam measurement system 150. The beam measurement system 150, for example, includes a beam profiler apparatus 200 for measuring a two-dimensional profile (e.g., uniformity along the x-axis, uniformity along the y-axis, and angles in the x-axis) of the ion beam 112, as will be discussed in greater detail hereafter.

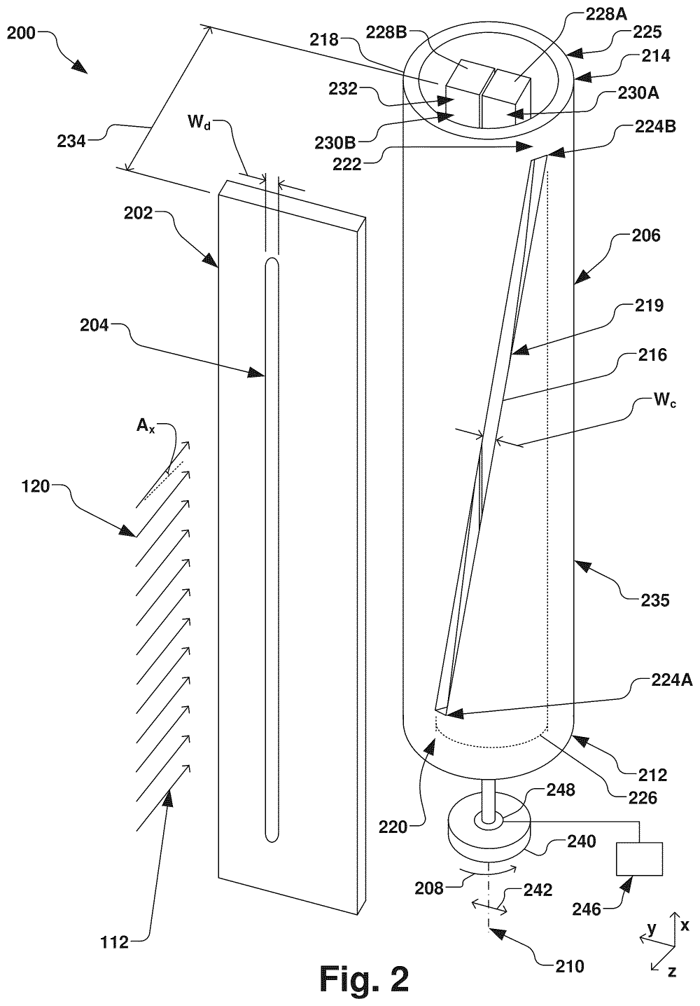

In accordance with one example of the disclosure, the beam profiler apparatus 200 shown in FIG. 2 comprises an aperture plate 202, wherein the aperture plate has a defining aperture slit 204 defined therein. The beam profiler apparatus 200, for example, further comprises a cylinder 206, wherein the cylinder is configured to rotate (e.g., illustrated by arrow 208) about a cylinder axis 210. The cylinder 206, for example, is generally hollow and extends along the cylinder axis 210 from a first end 212 to a second end 214. The cylinder 206, for example, comprises a circumferential slit 216 defined in a cylinder wall 218 thereof. The circumferential slit 216, for example, extends between approximately the first end 212 and approximately the second end 214 of the cylinder along an oblique path 219, whereby the oblique path is defined as not being parallel to the defining aperture slit 204. The circumferential slit 216, in one example, extends from a first region 220 proximate to the first end 212 to a second region 222 proximate to the second end 214. Although not shown, in another example, the circumferential slit 216 can extend fully from the first end 212 to the second end 214 of the cylinder 206.

The circumferential slit 216, for example, can extend from a first radial position 224A to a second radial position 224B about a circumference 225 of the cylinder 206 to define an angular span 226 of the circumferential slit 216. The circumferential slit 216, for example, can be thus defined as a helical, curvilinear, or otherwise-shaped slit defined through at least a portion of the circumference 225 of the cylinder wall 218 and extending between the first region 220 and the second region 222 of the cylinder 206.

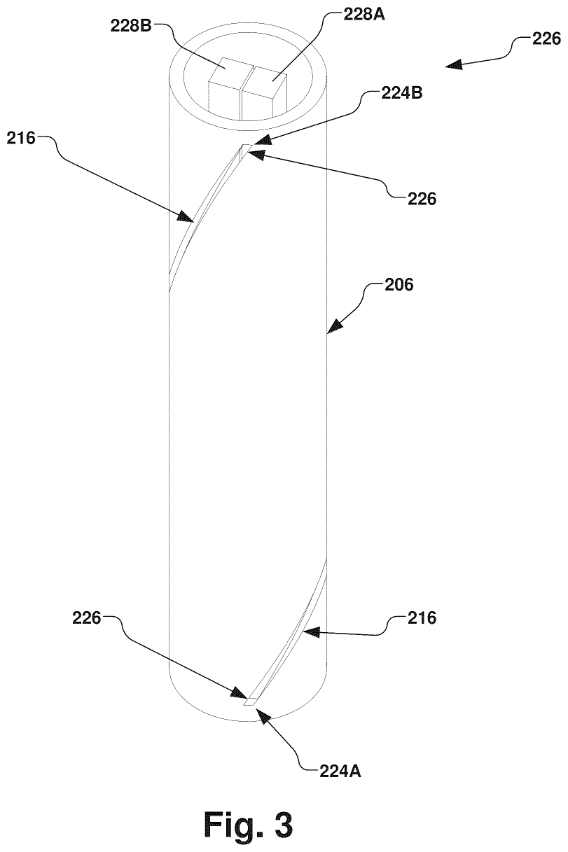

In accordance with one example of the disclosure, a circumferential slit width W_{c} of the circumferential slit 216, a defining aperture slit width W_{d} of the defining aperture slit 204, and the angular span 226 of the circumferential slit are configured to provide a desired precision or resolution of measurement capability of the beam profiler apparatus 200. For example, the angular span 226 of the circumferential slit 216 can be selected to be between approximately 90 degrees and approximately 360 degrees. In the example shown in FIG. 2, the angular span 226 of the circumferential slit 216 is approximately 90 degrees. FIG. 3 illustrates another example of the cylinder 206, wherein the angular span 226 of the circumferential slit 216 is approximately equal to 360 degrees.

While not shown, the present disclosure contemplates other examples where the angular span 226 of the circumferential slit 216 is greater than 360 degrees. Such a configuration of the circumferential slit 216 in the cylinder 206, for example, can provide greater resolution of the beam profiler apparatus 200, as will be appreciated hereafter. It is desirable, however, to maintain a structural integrity of the cylinder 206, whereby the configuration of the circumferential slit 216 can be balanced with a rotational speed of the cylinder in order to achieve the desired capability of the beam profiler apparatus 200.

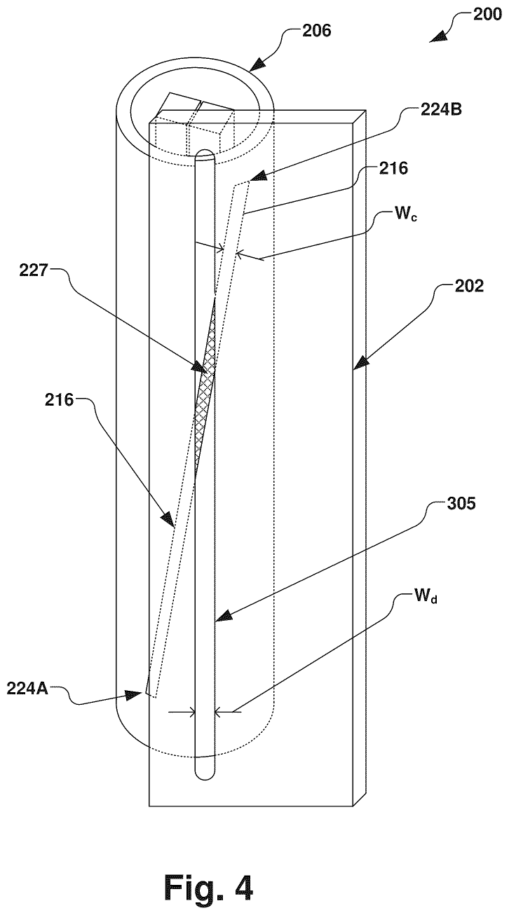

The present disclosure further contemplates that the spatial resolution or precision of the beam profiler apparatus 200 can be defined by a sample area 227 illustrated in FIG. 4 through which the ion beam 112 of FIG. 2 passes. For example, the angular span 226 of the circumferential slit 216 between the first radial position 224A and the second radial position 224B shown in FIG. 4, as well as the circumferential slit width W_{c} of the circumferential slit 216 and the defining aperture slit width W_{d} of the defining aperture slit 204 generally define the sample area 227. A desired resolution for measurement of the ion beam 112 by the beam profiler apparatus 200 can be achieved by controlling the sample area.

The beam profiler apparatus 200 of FIG. 2, for example, further comprises at least first and second beam current detectors 228A, 228B having respective first and second detector surfaces 230A, 230B disposed within the cylinder 206 and extending parallel to the cylinder axis 210 between the first end 212 and second end 214 of the cylinder. For example, relative to the cylinder axis 210, the first and second beam current detectors 228A, 228B extend from the first region 220 proximate to the first end 212 to the second region 222 proximate to the second end 214, thereby defining a detector plane 232 from approximately the first end of the cylinder to approximately the second end of the cylinder 206. The first and second beam current detectors 228A, 228B, for example, are configured to receive and detect current of any portion of an ion beam impinging on the each of the respective first and second detector surfaces 230A, 230B.

For example, the first and second beam current detectors 228A, 228B can comprise faraday detectors or other detectors operable to detect beam current associated with an impact of ions thereto. An example of a beam current detector is described in commonly-owned U.S. Pat. No. 5,198,676, the contents of which is incorporated by reference herein, in its entirety. The first and second beam current detectors 228A, 228B, for example, are configured to sense ion beam current to determine both y-axis uniformity of the ion beam, as well x-axis angle data, as will be discussed in greater detail, infra.

In accordance with the disclosure, the aperture plate 202, for example, is positioned upstream of the cylinder 206 along the beam path 120 at a predetermined offset distance 234 from the detector plane 232. The defining aperture slit 204, for example, extends generally parallel to the cylinder axis 210, wherein the defining aperture slit has a defining aperture slit width W_{d} defined generally perpendicular to the cylinder axis, such as being parallel to the y-axis. The defining aperture slit width W_{d} of the defining aperture slit 204, for example, generally defines an acceptance angle of the ion beam 112 through the defining aperture slit 204, thereby limiting an amount of ion beam current that is permitted to pass therethrough.

The cylinder 206, for example, can be considered to serve multiple measurement functions and can be further provided as a suppressed beam current detector 235. For example, one measurement function of the cylinder 206 is provided by the circumferential slit 216, whereby the circumferential slit acts as a mask to define a sample area and resolution along the y-axis. Another measurement function of the cylinder 206, for example, can be provided when the circumferential slit 216 is rotated past the defining aperture slit 204, whereby the cylinder acts as an x-axis suppressed beam current detector. In another example, a total beam current detected along the x-axis can be determined by a summation of all beam currents detected along the y-axis. The cylinder 206, itself, for example, can act as an electron suppression device, or contain suppressing magnets, such as described in co-owned U.S. Pat. No. 7,064,340, the contents of which is incorporated by reference herein, in its entirety.

As referred to above, the cylinder 206, for example, is configured to act as a mask to generally define the sample area 227 and resolution of the ion beam 112 associated with the y-axis, whereby the circumferential slit width W_{c} of the circumferential slit 216 and the defining aperture slit width W_{d} of the defining aperture slit 204 defines an amount of the ion beam 112 that may pass therethrough at an intersection of circumferential slit and defining aperture slit. A size of the circumferential slit width W_{c} of the circumferential slit 216 and the defining aperture slit width W_{d} of the defining aperture slit 204 can be configured such that the current passing through both the defining aperture slit and circumferential slit provides a desired minimum signal-to-noise ratio, and wherein the circumferential slit and defining aperture slit provide a desired spatial resolution, resulting in an angle resolution of 0.1 degrees or better in various examples. In contrast with U.S. Pat. No. 7,064,340, however, the defining aperture slit 204 of the present disclosure is fixed with respect to the first and second beam current detectors 228A, 228B, whereby the first and second beam current detectors are provided as a split detector, thus advantageously enabling the simultaneous angle measurement, as will be discussed in greater detail infra.

A rotary input apparatus 240, for example, is further operably coupled to the cylinder 206, wherein the rotary input apparatus is configured to selectively rotate the hollow cylinder about the cylinder axis 210, as indicated by arrow 208. The rotary input apparatus 240, for example, can comprise one or more of a motor, rotary shaft, or other rotational input mechanism operably (e.g., rotatably) coupled to the cylinder 206.

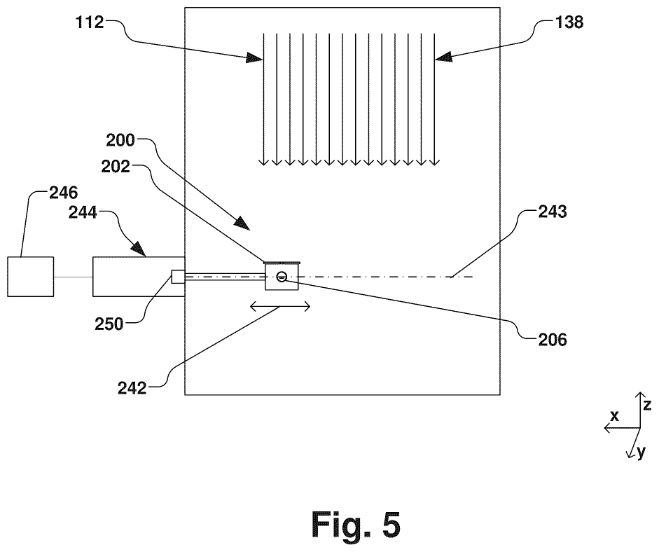

In accordance with another example aspect of the disclosure, the beam profiler apparatus 200 is further configured to translate the cylinder 206 and the aperture plate 202 with respect to the cylinder axis 210 (e.g., indicated by arrow 242) along a profiler path 243 via a translation apparatus 244, as illustrated in FIG. 5. In the present example, the profiler path 243 is linear, whereby the translation apparatus 244, for example, can comprise a linear actuator or other linear input mechanism operably coupled the cylinder 206 and the aperture plate 202 of FIG. 2, whereby the translation apparatus is configured to linearly translate or sweep the cylinder and the aperture plate along, or parallel to, the y-axis. In other examples, the profiler path 243 is arcuate or non-linear, whereby the translation apparatus 244 can be configured to translate the cylinder 206 and aperture plate 202 in a non-linear manner. The translation apparatus 244, for example, is further configured to selectively translate the cylinder 206 and the aperture plate 202 to a retracted position (not shown), whereby the hollow cylinder and aperture plate are not impacted by the ion beam 112 in the retracted position.

By translating the cylinder 206 and the aperture plate 202 with the defining aperture slit 204 extending generally parallel to the cylinder axis 210, sweeping the entire beam profiler apparatus 200 across the ion beam 112 thus further advantageously enables profiling of the ion dose and angles in the x-axis. In accordance with another example, positional feedback information associated with the rotary input apparatus 240 and the translation apparatus 244 can be provided by one or more feedback position apparatuses 246. For example, the one or more feedback position apparatuses 246 can comprise a rotational encoder 248 associated with the rotary input apparatus 240 shown in FIG. 2 and a linear encoder 250 associated with translation apparatus 244 shown in FIG. 5. As such, in one example, the one or more feedback position apparatuses 246 can be configured to provide rotational and linear position feedback associated with the beam profiler apparatus 200 to one or more of the beam measurement system 150 and controller 144 of FIG. 1, such that a linear position of the defining aperture slit 204 and an angular position of the circumferential slit 216 of FIG. 2 can be further known, determined, or acquired for the determination of the profile of the ion beam 112 discussed herein.

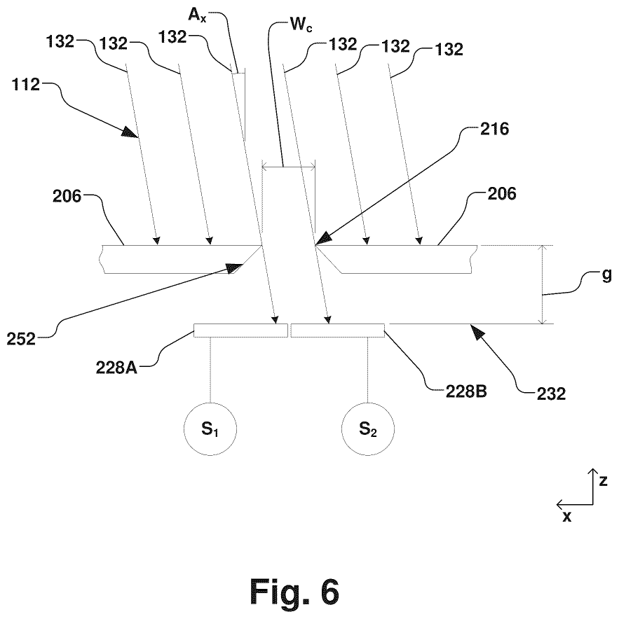

In accordance with the example illustrated shown in FIG. 6, the ion beam 112 passes through the defining aperture slit (not shown) and is measured by the first and second beam current detectors 228A, 228B after passing through the circumferential slit 216 of the cylinder 206 as it rotates, thus providing a first uniformity Uₓ of the ion beam along the x-axis over the width of the scanned beam. The present disclosure contemplates that all uniformities and angles in both the x-axis and y-axis can be determined by the first and second beam current detectors 228A, 228B. However, the present disclosure further contemplates the cylinder 206 acting as an electron suppression device, as discussed above, in order to provide an additional or redundant measurement.

In addition, as the circumferential slit 216 in the cylinder 206 intersects with the defining aperture slit 204, a portion of the ion beam 112 passes through both the circumferential slit and defining aperture slit to impinge on the first and second beam current detectors 228A, 228B positioned within the cylinder. As such, the resulting beam current measurements from the first and second beam current detectors 228A, 228B can be processed to define both angle of incidence Aₓ in the x-axis and uniformity U_{y} in the y-axis.

The cylinder 206, for example, is configured to rotate about the x-axis at a substantially faster rate than the translation along the x-axis. For example, the cylinder 206 can be configured to rotate at approximately 60 Hz, whereby the circumferential slit 216 is rotated approximately 60 times a second, while the translation of the beam profiler apparatus 200 along a translation length the x-axis (e.g., approximately 500 mm) is accomplished in approximately 6-10 seconds.

In accordance with one example, an angle of incidence Aₓ of the ion beam 112 in the x-axis can be determined, such as provided in U.S. Pat. No. 6,677,598, the contents of which are incorporated herein in its entirety. For example, the angle of incidence Aₓ of the ion beam 112 in the x-axis can be determined by:

$${A}_{x} = \frac{( {S}_{1} - {S}_{2} )}{( {S}_{1} + {S}_{2} )} * \frac{{W}_{d}}{2 g} , \qquad ( 1 )$$

where S₁ is the ion beam current detected by the first beam current detector 228A, S₂ is the ion beam current detected by the second beam current detector 228B, is the defining aperture slit width W_{d} of the defining aperture slit 204 and g is the predetermined offset distance 234 separating the defining aperture slit from the detector plane 232 associated with the first and second beam current detectors 228A, 228B. A second uniformity U_{y} of the ion beam 112 along the y-axis is:

$${U}_{y} = {S}_{1} + {S}_{2} . \qquad ( 2 )$$

Accordingly, the beam profiler apparatus 200 is thus configured to concurrently (e.g., simultaneously) determine the uniformity of the ion beam 112 in two dimensions (e.g., the first uniformity Uₓ in the x-axis and the second uniformity U_{y} in the y-axis), as well as the angular distribution Aₓ in the x-axis. The beam profiler apparatus 200, for example, measures the beamlets 132 of the ion beam 112 at two different locations in the x-direction via the first and second beam current detectors 228A, 228B, whereby all beamlets in the y-direction are collected by the same collector. In the y-direction, the circumferential slit 216 of the cylinder 206 (e.g., a rotating mask), in conjunction with the defining aperture slit 204 of FIG. 2 are configured to collect current associated with such a vertically moving opening, thus measuring a vertical current density distribution, from which uniformity, height and position of the ion beam 112 within the beam path 120 can be calculated or otherwise determined. Accordingly, the present disclosure is advantageous over conventional systems and apparatuses, whereby ion beam tuning can be shortened by eliminating independent and sequential measurements of uniformity and angular distribution.

For example, when the ion beam 112 passes through both the defining aperture slit 204 and the circumferential slit 216 at an intersection of the defining aperture slit and circumferential slit when viewed along the z-axis, the beam current of the ion beam is measured by the first and second beam current detectors 228A, 228B. A comparison or difference between the currents measured by the first and second beam current detectors 228A, 228B, for example, is utilized to determine the angle Aₓ of the ion beam 112 along the x-axis. For example, as illustrated in FIG. 6, the ion beam 112 (e.g., the parallelized ion beam 138) is illustrated as the angle Aₓ with respect to the detector plane 232, whereby a first beam current S₁ detected by the first beam current detector 228A can differ from a second beam current S₂ detected by the second beam current detector 228A. Accordingly, the angle Aₓ at which the ion beam 112 impinges on the detector plane 232 can be determined by equation (1), above.

For example, in order to gain a better understanding, as illustrated in FIG. 6, when considering only impingement angles Aₓ along the x-axis, the circumferential slit 216 in the cylinder wall 218 can be considered to be translated or scanned relative to the first and second beam current detectors 228A, 228B as the cylinder 206 is rotated about the cylinder axis 210 of FIG. 2. As the ion beam 112 impinges each of the first and second beam current detectors 228A, 228B, a difference in the beam current measured by the respective beam detectors can be attained at any given time. A position of the circumferential slit 216, for example, is further known at any given time based on feedback from the rotary input apparatus 240 of FIG. 2 and feedback from the translation apparatus 244 of FIG. 5, whereby the angle Aₓ of the ion beam 112 with respect to the detector plane 232 can be derived from equation (1) at any position of the beam profile apparatus along the x-axis. Accordingly, based on the rotation 208 of the cylinder 206 and the measured beam current from the first and second beam current detectors 228A, 228B, the angle Aₓ at which the ion beam 112 is presented to the workpiece 124 of FIG. 1 can be derived.

The circumferential slit 216 in the cylinder wall 218, for example, comprises a bevel 252, whereby the bevel generally provides what is referred to as a “knife edge” to allow for an acceptance of a multitude of angles Aₓ to be measured without being affected by an overall thickness of the cylinder wall. The bevel 252, for example, is provided at an angle that is greater than any reasonable angle Aₓ at which the ion beam 112 can be presented to the detector plane 232.

The present disclosure is advantageous over conventional profiling apparatuses, as the present disclosure an utilize one pass of the beam profiling apparatus 200 through the ion beam 112 to tune in multiple dimensions, whereas conventional systems would implement multiple passes through the ion beam to attain similar results. For example, conventionally, one pass of a profiler through the ion beam would be performed determining current density distribution in the x-axis, and another pass of the profiler through the ion beam would be performed for measuring x-axis angles, whereby additional passes would then be implemented to confirm any respective corrections made in the ion implantation system. The present disclosure thus measures a 2-dimensional (e.g., x,y) current density distribution and a 2-dimensional (e.g., x,y) current-weighted x-angle (Aₓ) distribution in a single pass, from which both the x-axis and y-axis uniformity and x-axis angles can be calculated, whereby any correction or tuning of the ion implantation system 100 of FIG. 1 can be performed after simply the single pass.

Further, in accordance with another example, feedback from the beam profiler apparatus 200 can be provided to the workpiece scanning apparatus 140 of FIG. 1, whereby productivity can be further enhanced by optimizing a length of travel of the workpiece 124 through the ion beam 112 in order to obtain a uniform dose distribution at the workpiece. For example, the present disclosure provides for productivity enhancement by optimizing a length of the mechanical scan of the workpiece 124 in the x-axis based the measurement profile associated with the y-axis. As such, a size of the ion beam 112 and a length of the mechanical scan of the workpiece 124 can be optimized based on the profile of the beam and a size of the workpiece.

For example, for an ion beam 112 having a uniform profile height of 100 mm beam in the y-axis when implanting into a workpiece 124 having a diameter of 300 mm in accordance with the present disclosure, a total mechanical scan of 500 mm would be performed in order to attain a 100 mm over-scan at respective (e.g., top/bottom) edges of the workpiece to attain the desired uniformity. However, with the attainment of the profile of the ion beam 112 in accordance with the present disclosure, if the ion beam is determined to have a uniform profile height of 50 mm, using the same workpiece diameter of 300 mm, the over-scan could be limited to 50 mm on the edges to provide a uniform implantation, thus providing a mechanical scan of only 400 mm, and increasing productivity of the ion implantation system. It should be noted that the length of the over-scan can be further reduced, at reduced margins for error, to further increase productivity.

In another example, feedback can be utilized for controlling a length of the scanning of the ion beam 112 in the x-axis via a magnet (e.g., the ion beam scanning apparatus 126) upstream of the workpiece 124, as well as the mechanical scanning of the workpiece in the y-axis via the workpiece scanning apparatus 140. Further, data from the beam profiling apparatus 200 can be utilized by the controller to control the collimator 134 to correct the x-axis angles.

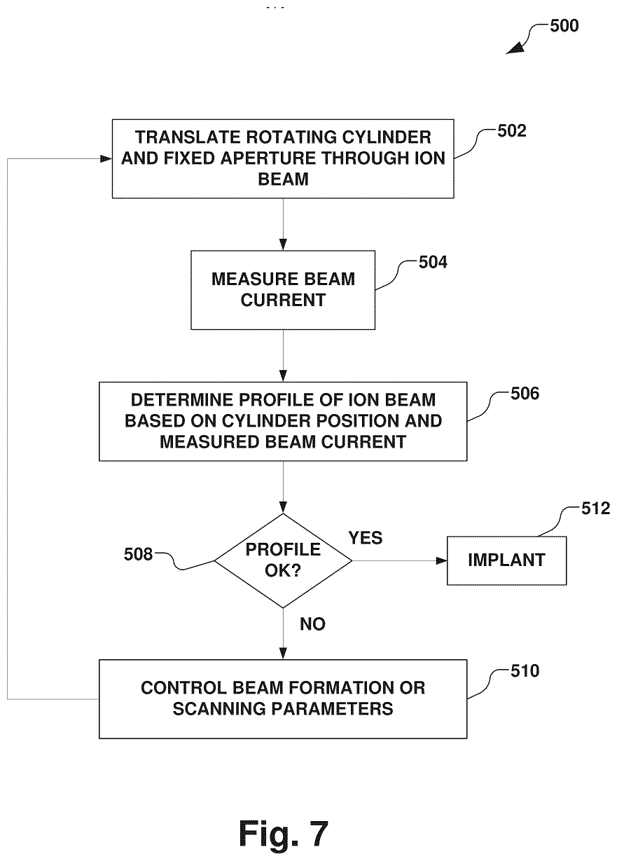

In accordance with yet another exemplary aspect, a method 500 is provided in FIG. 7 for profiling and tuning an ion beam in an ion implantation system, such as in the ion implantation system 100 of FIG. 1. It should be noted that while exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

As illustrated in FIG. 7, in accordance with one example, the method 500 comprises translating a rotating cylinder and a fixed aperture plate through the ion beam in act 502. In act 504, for example, a beam current of the ion beam is measured by two or more beam current detectors at a workpiece plane, where the ion beam passes through a slit in the aperture plate and a circumferential slit in the cylinder prior to impinging on the workpiece plane while the cylinder is rotated and passed linearly through the scanned ion beam. In act 506, a profile of the ion beam is determined based, at least in part, on the measured beam current and linear and rotational positional information associated the rotating and translating cylinder. The profile of the ion beam determined in act 506, for example, comprises a two-dimensional (e.g., x-y) profile of the ion beam, along with an angle of incidence in at least one direction as the ion beam impinges on the workpiece plane. In act 508, if one or more predetermined conditions of uniformity are met, the method ends. If the one or more predetermined conditions of uniformity are not met, the method continues to act 510, whereby one or more parameters associated with a formation and/or scanning of the ion beam are controlled based on the profile of the ion beam that was determined in act 506. The method then repeats to act 502 until the one or more predetermined conditions of uniformity are met in act 508, whereby ion implantation may commence in act 512.

Although the invention has been illustrated and described with respect to one or more implementations, alterations and/or modifications may be made to the illustrated examples without departing from the spirit and scope of the appended claims. In particular regard to the various functions performed by the above described components or structures (blocks, units, engines, assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. The term “exemplary” as used herein is intended to imply an example, as opposed to best or superior. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A profiler apparatus for determining a profile of an ion beam along a beam path, the profiler apparatus comprising:
a hollow cylinder comprising a cylinder wall having an circumferential slit defined therethrough;
a rotation apparatus operably coupled to the hollow cylinder and configured to selectively rotate the hollow cylinder about a first axis, thereby defining a rotational position of the circumferential slit;
an aperture plate having a defining aperture slit defined therethrough, wherein the aperture plate is fixed relative to the rotation apparatus, and wherein the defining aperture slit is positioned a predetermined distance from of the hollow cylinder along the beam path;
a translation apparatus operably coupled to the hollow cylinder and the aperture plate, wherein the translation apparatus is configured to translate the hollow cylinder and the aperture plate along a second axis, thereby defining a linear position of the defining aperture slit; and
a current detection apparatus comprising a first current detector and a second current detector, wherein the first current detector and the second current detector are positioned within the hollow cylinder and configured to respectively detect a first current and a second current of the ion beam passing through the defining aperture slit and circumferential slit and impacting thereon concurrent with the selective rotation of the hollow cylinder; and
a controller configured to determine a first uniformity of the ion beam defined along the first axis, a second uniformity of the ion beam defined along the second axis, and an angle of incidence of the ion beam with respect to the first axis based, at least in part, on the first current, the second current, the rotational position of the circumferential slit, and the linear position of the defining aperture slit.

2. The profiler apparatus of claim 1, further comprising one or more feedback apparatuses, wherein the one or more feedback apparatuses are configured to provide one or more of the rotational position of the circumferential slit and the linear position of the defining aperture slit to the controller.

3. The profiler apparatus of claim 1, wherein the second uniformity of the ion beam is based on a sum of the first current and the second current at the rotational position of the circumferential slit and the linear position of the defining aperture slit.

4. The profiler apparatus of claim 1, wherein the ion beam comprises a scanned ion beam, wherein the scanned ion beam is scanned along the second axis.

5. The profiler apparatus of claim 1, wherein the circumferential slit extends from a first radial position to a second radial position with respect to the first axis, thereby defining an angular span of the circumferential slit.

6. The profiler apparatus of claim 5, wherein the angular span is less than 360 degrees.

7. The profiler apparatus of claim 1, wherein the circumferential slit and the defining aperture slit have respective widths that are smaller than a width of the ion beam.

8. The profiler apparatus of claim 1, wherein the translation apparatus is further configured to selectively translate the hollow cylinder and the aperture plate to a retracted position, whereby the hollow cylinder and the aperture plate are not impacted by the ion beam in the retracted position.

9. The profiler apparatus of claim 1, wherein the circumferential slit comprises a bevel defined in the cylinder wall, whereby the bevel is configured to provide a maximum acceptance the ion beam therethrough.

10. The profiler apparatus of claim 1, wherein the defining aperture slit is positioned the predetermined distance upstream of the hollow cylinder along the beam path.

11. A profiler apparatus for profiling an ion beam, the profiler apparatus comprising:
an aperture plate having a defining aperture slit defined therein, wherein the defining aperture slit extends parallel to a first axis;
a hollow cylinder extending parallel to the first axis, wherein the hollow cylinder comprises a cylinder wall having a circumferential slit defined therein, and wherein the hollow cylinder is rotatable about the first axis;
a pair of detectors positioned along the first axis within the hollow cylinder, wherein the pair of detectors are fixed with respect to the aperture plate and configured to respectively detect a current of at least a portion of the ion beam as the at least a portion of the ion beam passes through the defining aperture slit and the circumferential slit; and
a translation apparatus configured to translate the aperture plate, the hollow cylinder and the pair of detectors with respect to a second axis, wherein the second axis is approximately perpendicular to the first axis.

12. The profiler apparatus of claim 11, further comprising a controller configured to determine a first uniformity of the ion beam defined along the first axis, a second uniformity of the ion beam defined along the second axis, and an angle of incidence of the ion beam with respect to the first axis based, at least in part, on a rotational position of the circumferential slit, and a linear position of the defining aperture slit, and the current of the at least a portion of the ion beam.

13. The profiler apparatus of claim 12, further comprising one or more feedback apparatuses, wherein the one or more feedback apparatuses are configured to determine one or more of the rotational position of the circumferential slit and the linear position of the defining aperture slit.

14. The profiler apparatus of claim 11, further comprising a rotation apparatus operably coupled to the hollow cylinder and configured to selectively rotate the hollow cylinder about the first axis.

15. The profiler apparatus of claim 11, wherein the defining aperture slit is positioned a predetermined distance upstream of the hollow cylinder with respect to a path of the ion beam.

16. The profiler apparatus of claim 11, wherein the circumferential slit extends from a first radial position to a second radial position with respect to the first axis, thereby defining an angular span of the circumferential slit.

17. An ion implantation system comprising:
an ion source configured to form an ion beam along a beam path;
one or more beam defining devices positioned downstream of the ion source and configured to control one or more properties of the ion beam as the ion beam travels along the beam path for implantation into a workpiece;
an ion beam scanning apparatus configured to selectively scan the ion beam along a first axis, thereby defining a scanned ion beam; and
a profiler apparatus for determining a profile of the scanned ion beam along the beam path, the profiler apparatus comprising:
a cylinder apparatus comprising:
a first detector positioned along the beam path and extending parallel to the first axis, wherein the first detector is configured to detect a first current of at least a portion of the scanned ion beam upon exposure thereto;
a second detector positioned along the beam path and extending parallel to the first axis, wherein the second detector is configured to detect a second current of the portion of the scanned ion beam upon exposure thereto;
a rotary input apparatus; and
a hollow cylinder operably coupled to the rotary input apparatus, wherein the rotary input apparatus is configured to selectively rotate the hollow cylinder about the first axis, wherein the hollow cylinder comprises a cylinder wall encircling the first detector and the second detector, and wherein the cylinder wall comprises a circumferential slit defined therethrough;
an aperture plate having an aperture slit defined therethrough, wherein the aperture slit extends parallel to the first axis and is defined by an aperture slit width extending along a second axis that is approximately perpendicular to the first axis, and wherein the aperture slit is positioned a predetermined distance upstream of the hollow cylinder along the beam path;
a linear translation apparatus operably coupled to the cylinder apparatus and the aperture plate, wherein the linear translation apparatus is configured to linearly translate the cylinder apparatus and the aperture plate along the second axis; and
a controller configured to determine a first uniformity of the scanned ion beam along the first axis, a second uniformity of the scanned ion beam along the second axis, and an angle of incidence of the scanned ion beam with respect to the first axis based, at least in part, on the first current, the second current, a rotational position of the circumferential slit, and a linear position of the aperture slit.

18. The ion implantation system of claim 17, further comprising one or more feedback apparatuses, wherein the one or more feedback apparatuses are configured to provide one or more of the rotational position of the circumferential slit and the linear position of the aperture slit to the controller.

19. The ion implantation system of claim 18, wherein the one or more feedback apparatuses comprise a linear encoder operably coupled to the linear translation apparatus and a rotational encoder operably coupled to the cylinder apparatus.

20. The ion implantation system of claim 17, wherein the second uniformity is based on a sum of the first current and the second current at the rotational position of the circumferential slit and the linear position of the aperture slit.

21. The ion implantation system of claim 17, wherein each of the first detector and the second detector comprise a respective detector surface facing the scanned ion beam, wherein the first detector and the second detector are stationary with respect to the aperture plate.
